(19) United States
(12) Patent Application Publication
(10) Pub. No.: US 2026/0313977 A1
(43) Pub. Date: Oct. 8, 2026

(54) GATE STRUCTURES WITH PROTECTION LAYER FOR SEMICONDUCTOR DEVICES

(71) Applicant: Taiwan Semiconductor Manufacturing Company, Ltd., Hsinchu (TW)

(72) Inventors: Han-Jyun HOU, Hsinchu (TW); Cheng-Yi PENG, Taipei (TW); Tsung-Chieh HSIAO, Changhua (TW); Chih-Lin WANG, Hsinchu (TW)

(73) Assignee: Taiwan Semiconductor Manufacturing Company, Ltd., Hsinchu (TW)

(21) Appl. No.: 19/295,588

(22) Filed: Aug. 9, 2025

Related U.S. Application Data
(60) Provisional application No. 63/783,009, filed on Apr. 3, 2025.

(51) Int. Cl. H10D 62/10; H10D 30/00; H10D 30/01; H10D 30/43; H10D 64/66; H10D 84/01; H10D 84/83

(52) U.S. Cl. CPC H10D 62/102; H10D 30/017; H10D 30/019; H10D 30/43; H10D 30/502; H10D 62/121; H10D 64/664; H10D 64/666; H10D 64/669; H10D 84/0172; H10D 84/832

(57) ABSTRACT

The present disclosure describes a semiconductor device having gate structures with a protection layer. The semiconductor device includes a gate dielectric layer on a channel structure, an aluminum-free work function metal layer on the gate dielectric layer, a protection layer on the aluminum-free work function metal layer, and an aluminum-containing work function metal layer on the protection layer.

### CROSS-REFERENCE TO RELATED APPLICATION

This application claims the benefit of U.S. Provisional Patent Application No. 63/783,009, titled “MG Structure with Top Protective Layer to Enhance Gap Fill and Device Performance,” filed Apr. 3, 2025, the disclosure of which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (FinFETs) ), gate-all-around field effect transistors (GAAFETs), complementary field effect transistors (CFETs), nanosheet transistors, nanowire transistors, multi-bridge channel transistors, nano-ribbon transistors, and other similar-structured transistors. Such scaling down has increased the complexity of semiconductor manufacturing processes and increased the difficulty of process and defect control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having gate structures with a protection layer, in accordance with some embodiments.

FIG. 2 illustrates a partial cross-sectional view of a semiconductor device having gate structures with a protection layer, in accordance with some embodiments.

FIG. 3 illustrates another partial cross-sectional view of a semiconductor device having gate structures with a protection layer, in accordance with some embodiments.

FIG. 4 is a flow diagram of a method for fabricating a semiconductor device having gate structures with a protection layer, in accordance with some embodiments.

FIGS. 5-23 illustrate partial cross-sectional views of a semiconductor device having gate structures with a protection layer at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20 % of the value (e.g., ±1 %, ±2 %, ±3 %, ±4 %, ±5 %, ±10 %, ±20 % of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, a nanostructure transistor on a substrate can have a gate structure surrounding a channel structure to improve device performance. The gate structure can include a metal fill and multiple work function metal layers to tune the threshold voltage of the nanostructure transistor. With the continuous scaling down of the device dimensions, the gate structure may not have enough space for the metal fill and the multiple work function metal layers, which can lead to the increase of gate resistance and the decrease of device performance. Additionally, the continuous scaling down of the multiple work function metal layers may reduce the barrier of element diffusion from the gate structure towards the channel structure and may cause device reliability issues.

Various embodiments in the present disclosure provide methods for forming gate structures with a protection layer in a semiconductor device (e.g., a nanostructure transistor) and/or other semiconductor devices in an integrated circuit (IC). In some embodiments, a semiconductor device can include a channel structure on a substrate. A gate dielectric layer can be disposed on the channel structure. An aluminum-free work function metal layer can be disposed on the gate dielectric layer and can surround the channel structure. A protection layer can be disposed on the aluminum-free work function metal layer. An aluminum-containing work function metal layer can be disposed on the protection layer. A metal fill can be disposed on the aluminum-containing work function metal layer. In some embodiments, the protection layer can block the aluminum diffusion from the aluminum-containing work function metal layer towards the gate dielectric layer and the channel structure and improve the reliability of the semiconductor device. In some embodiments, with the protection layer, a thickness of the aluminum-free work function metal layer can be scaled down and the space for the metal fill can increase, which can reduce the gate resistance of the semiconductor device and improve the device performance.

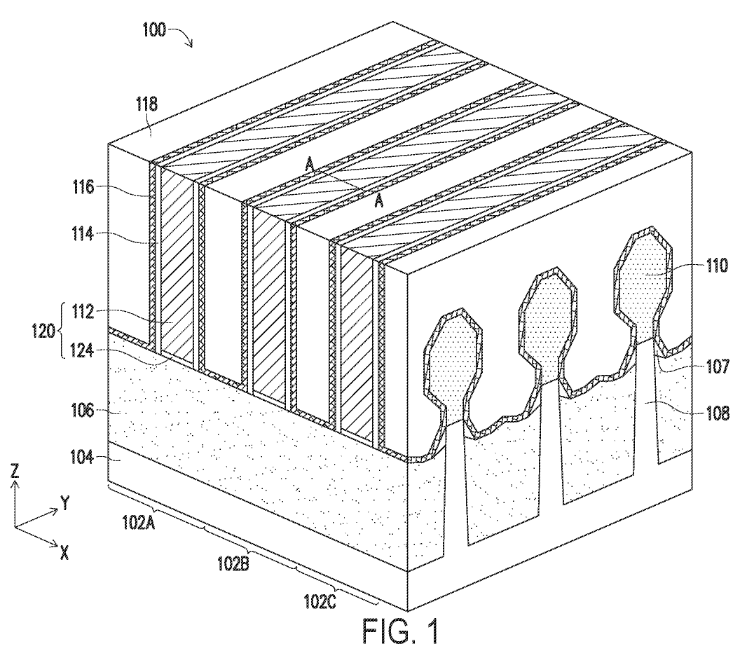

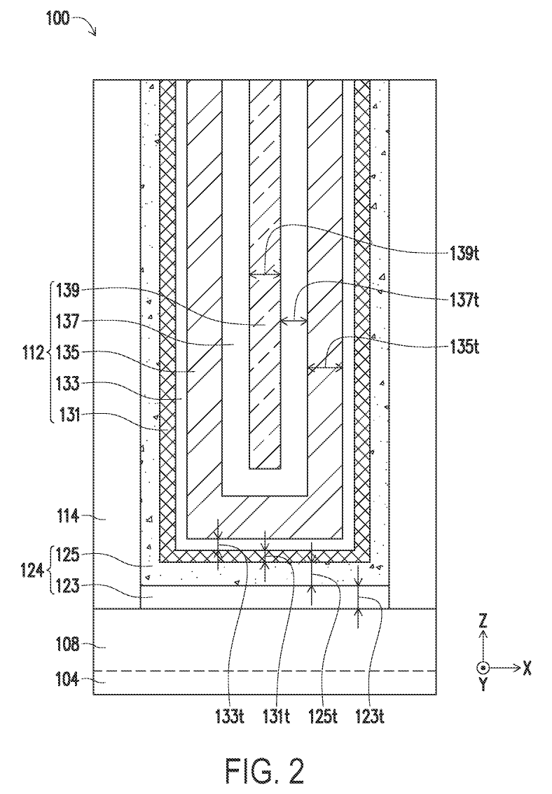

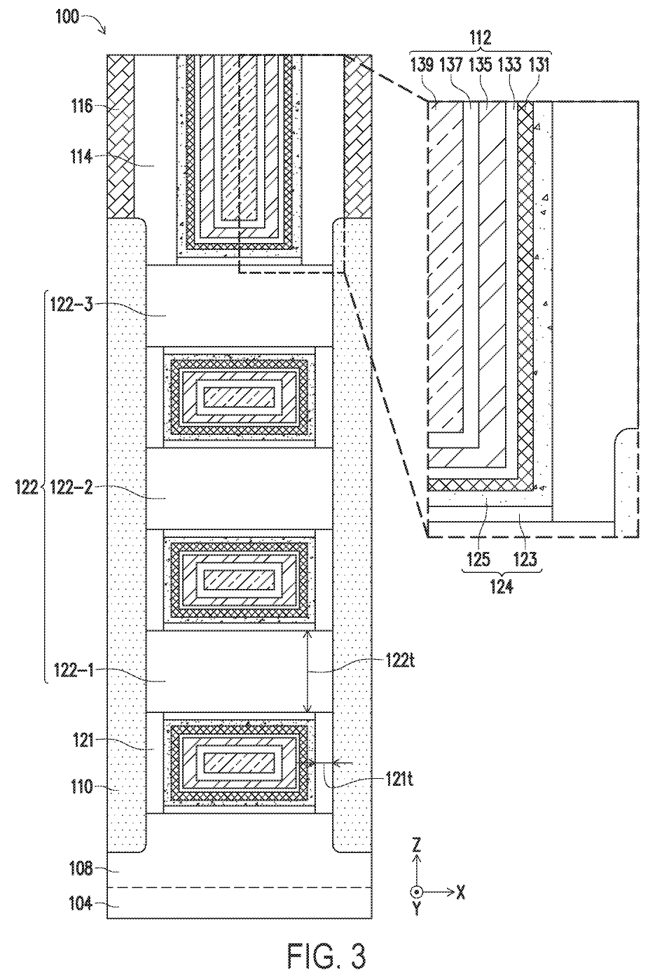

FIG. 1 illustrates an isometric view of a semiconductor device 100 having gate structures with a protection layer, in accordance with some embodiments. FIGS. 2 and 3 illustrate partial cross-sectional views of various embodiments of semiconductor device 100 across line A-A shown in FIG. 1. In some embodiments, semiconductor device 100 can include transistors 102A-102C, as shown in FIG. 1. In some embodiments, transistors 102A-102C can include nanostructure transistors. The nanostructure transistors can include FinFETs, gate-all-around field effect transistors (GAA FETs), nanosheet transistors, nanowire transistors, multi-bridge channel transistors, nano-ribbon transistors, and other similar-structured transistors.

In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. Though FIG. 1 shows three transistors, semiconductor device 100 can have any number of transistors with different sizes. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1-3, semiconductor device 100 having transistors 102A-102C can be formed on a substrate 104 and can be isolated by shallow trench isolation (STI) regions 106. In some embodiments, as shown in FIGS. 1 and 2, each of transistors 102A-102C can include fin structures 108, sidewall spacers 107, gate structures 120, gate spacers 114, S/D structures 110, etch stop layer (ESL) 116, and interlayer dielectric (ILD) layer 118. In some embodiments, as shown in FIGS. 1 and 3, each of transistors 102A-102C can include fin structures 108, nanostructures 122-1, 122-2, and 122-3 (collectively referred to as “nanostructures 122”), sidewall spacers 107, gate structures 120, gate spacers 114, inner spacers 121, S/D structures 110, ESL 116, and ILD layer 118.

Referring to FIGS. 1-3, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1 and 2, fin structures 108 can be formed on patterned portions of substrate 104. Referring to FIGS. 1 and 3, nanostructures 122 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

In some embodiments, as shown in FIGS. 1 and 2, fin structures 108 can extend along an X-axis for transistors 102A-102C. In some embodiments, fin structures 108 can be disposed on substrate 104. In some embodiments, a first portion of fin structures 108 under gate structures 120 can extend above a second portion of fin structures 108 under S/D structures 110. In some embodiments, the first portion of fin structures 108 under gate structures 120 can act as a channel structure and can form a channel region of transistors 102A-102C.

In some embodiments, as shown in FIGS. 1 and 3, nanostructures 122 and fin structures 108 can extend along an X-axis for transistors 102A-102C. In some embodiments, nanostructures 122 and fin structures 108 can be disposed on substrate 104. Nanostructures 122 can include a set of nanostructures 122-1, 122-2, and 122-3, which can be in the form of semiconductor layers, nanosheets, nanowires, or nanoribbons. Each of nanostructures 122 can act as a channel structure and can form a channel region underlying gate structures 120 of transistors 102A-102C.

In some embodiments, nanostructures 122 and fin structures 108 can include semiconductor materials similar to or different from substrate 104. In some embodiments, nanostructures 122 and fin structures 108 can include silicon. The semiconductor materials of nanostructures 122 and fin structures 108 can be undoped or can be in-situ doped during their formation process. In some embodiments, as shown in FIG. 2, the first portion of fin structures 108 under gate structures 120 can form channel regions of semiconductor device 100 and represent current carrying channel structures of semiconductor device 100. In some embodiments, as shown in FIG. 3, nanostructures 122 under gate structures 120 can form channel regions of semiconductor device 100 and represent current carrying channel structures of semiconductor device 100. In some embodiments, as shown in FIG. 3, nanostructures 122 can have a thickness 122t along a Z-axis ranging from about 3nm to about 15nm. Though three layers of nanostructures 122 are shown in FIG. 3, transistors 102A-102C can have any number of nanostructures 122.

Referring to FIGS. 1-3, gate structures 120 can include gate dielectric layer 124 and gate electrode 112. In some embodiments, gate dielectric layer 124 can be formed on nanostructures 122, fin structures 108, and STI regions 106. In some embodiments, as shown in FIGS. 1-3, gate dielectric layer 124 can be disposed on fin structures 108 and nanostructures 122 between a pair of gate spacers 114. In some embodiments, as shown in FIGS. 2 and 3, gate dielectric layer 124 can be multi-layered structures and can include an interfacial layer 123 and a high-k dielectric layer 125. In some embodiments, interfacial layer 123 can include silicon oxide formed by an oxidation process or a deposition process. In some embodiments, interfacial layer 123 can have a thickness 123t ranging from about 0.1nm to about 1.5nm. In some embodiments, high-k dielectric layer 125 can include hafnium oxide, zirconium oxide, or other suitable high-k dielectric materials. In some embodiments, high-k dielectric layer 125 can have a thickness 125t ranging from about 0.2nm to about 10nm.

In some embodiments, as shown in FIGS. 1 and 2, gate electrode 112 can be disposed on gate dielectric layer 124 over the first portion of fin structures 108. In some embodiments, as shown in FIGS. 1 and 3, gate electrode 112 can be disposed on gate dielectric layer 124 wrapped around nanostructures 122. In some embodiments, gate electrode 112 for NFET and PFET devices can have the same work-function metal. In some embodiments, gate electrode 112 for NFET and PFET devices can have different work-function metals. In some embodiments, as shown in FIG. 3, each of nanostructures 122 can be wrapped around by gate structures 120, for which gate structures 120 can be referred to as “gate-all-around (GAA) structures” and transistors 102A-102C can also be referred to as “GAA FETs 102A-102C.”

Gate electrode 112 can include work function metals to tune the threshold voltage (Vₜ) of transistors 102A-102C. In some embodiments, transistors 102A-102C can include any number of work function metal layers for Vₜ tuning (e.g., ultra-low Vₜ, low Vₜ, and standard Vₜ). In some embodiments, as shown in FIGS. 2 and 3, gate electrode 112 can include an aluminum-free work function metal layer 131, a protection layer 133, an aluminum-containing work function metal layer 135, a glue layer 137, and a metal fill 139. In some embodiments, as shown in FIGS. 1-3, top surfaces of ILD layer 118, ESL 116, gate spacers 114, gate dielectric layer 124, aluminum-free work function metal layer 131, protection layer 133, aluminum-containing work function metal layer 135, glue layer 137, and metal fill 139 can be coplanar. In some embodiments, aluminum-free work function metal layer 131 and aluminum-containing work function metal layer 135 can include work function metals to tune the Vₜ of transistors 102A-102C.

In some embodiments, aluminum-free of aluminum-free work function metal layer 131 can refer to an aluminum level below a threshold value, such as about 1.2 atomic percent. In some embodiments, aluminum-free work function metal layer 131 can also be referred to as “p-type work function metal layer 131,” referring to work function metal layers responsible for tuning, primarily, the threshold voltage of p-type FETs (and to a much lesser degree the threshold voltage of the n-type FETs). In some embodiments, n-type FETs may not be affected by the presence of the p-type work function metal layers. In some embodiments, aluminum-free work function metal layer 131 can include titanium nitride, titanium silicon nitride, tantalum nitride, tungsten carbon nitride, tungsten, ruthenium, molybdenum, or other suitable work function materials. In some embodiments, aluminum-free work function metal layer 131 can include materials having a work function greater than about 4.4 eV. In some embodiments, aluminum-free work function metal layer 131 can include a single metal layer or a stack of metal layers. The stack of metal layers can include work function metals having work-function values equal to or different from each other.

In some embodiments, aluminum-free work function metal layer 131 can have a thickness 131t ranging from about 0.1nm to about 8nm. In some embodiments, a ratio of thickness 131t to thickness 125t can range from about 0.5 to about 0.8. If thickness 131t is less than about 0.1nm or the ratio is less than about 0.5, aluminum-free work function metal layer 131 may not be able to tune the Vₜ of transistors 102A-102C. If thickness 131t is greater than about 8nm or the ratio is greater than about 0.8, gate electrode 112 may not have enough space for metal fill 139 and the resistance of gate electrode 112 may increase.

In some embodiments, aluminum-containing work function metal layer 135 can also be referred to as “n-type work function metal layer 135,” referring to work function layers responsible for tuning, primarily, the threshold voltage of n-type FETs. In some embodiments, aluminum-containing work function metal layer 135 can be present in each transistor of semiconductor device 100. In some embodiments, aluminum-containing work function metal layer 135 can include aluminum, titanium aluminum, titanium aluminum carbon, tantalum aluminum, tantalum aluminum carbon, or other suitable work function material. In some embodiments, aluminum-containing work function metal layer 135 can include materials having a work function less than about 4.4 eV. In some embodiments, aluminum-containing work function metal layer 135 can include a single metal layer or a stack of metal layers. The stack of metal layers can include work function metals having work-function values equal to or different from each other.

In some embodiments, aluminum-containing work function metal layer 135 can have a thickness 135t ranging from about 0.2nm and about 8nm. In some embodiments, a ratio of thickness 135t to thickness 125t can range from about 0.75 to about 1.0. If thickness 135t is less than about 0.2nm or the ratio is less than about 0.75, aluminum-containing work function metal layer 135 may not be able to tune the Vₜ of transistors 102A-102C. If thickness 135t is greater than about 8nm or the ratio is greater than about 1.0, gate electrode 112 may not have enough space for metal fill 139 and the resistance of gate electrode 112 may increase.

In some embodiments, as shown in FIGS. 2 and 3, protection layer 133 can be disposed between aluminum-free work function metal layer 131 and aluminum-containing work function metal layer 135. In some embodiments, protection layer 133 can include a conductive material having elements of oxygen and/or carbon. In some embodiments, protection layer 133 can include titanium carbonitride, titanium oxynitride, tungsten carbonitride, titanium silicon oxide, or other suitable conductive materials. In some embodiments, protection layer 133 can block the diffusion of aluminum from aluminum-containing work function metal layer 135 towards aluminum-free work function metal layer 131 and gate dielectric layer 124. Aluminum diffused to gate dielectric layer 124 can cause device reliability issues. With protection layer 133, aluminum diffusion from aluminum-containing work function metal layer 135 can be blocked and device reliability of semiconductor device 100 can be improved.

In some embodiments, protection layer 133 can have a thickness 133t ranging from about 0.05nm and about 2nm. In some embodiments, a ratio of thickness 133t to thickness 125t can range from about 0.1 to about 0.3. If thickness 133t is less than about 0.05nm or the ratio is less than about 0.1, protection layer 133 may not be able to block aluminum diffusion from aluminum-containing work function metal layer 135 and device reliability of semiconductor device 100 may be reduced. If thickness 133t is greater than about 2nm or the ratio is greater than about 0.3, gate electrode 112 may not have enough space for metal fill 139 and the resistance of gate electrode 112 may increase.

In some embodiments, as shown in FIGS. 2 and 3, glue layer 137 can be disposed on aluminum-containing work function metal layer 135. In some embodiments, glue layer 137 can provide sufficient bonding between metal fill 139 and aluminum-containing work function metal layer 135. In some embodiments, glue layer 137 can include cobalt, titanium, titanium nitride, titanium silicon oxide, or other suitable conductive materials. In some embodiments, glue layer 137 can have a thickness 137t ranging from about 0.2nm to about 10nm. In some embodiments, glue layer 137 is optional and gate electrode 112 can include no glue layer and more metal fill 139 to have a lower resistance.

In some embodiments, as shown in FIGS. 2 and 3, metal fill 139 can be disposed on glue layer 137. In some embodiments, metal fill 139 can include titanium, tantalum, aluminum, cobalt, tungsten, nickel, ruthenium, or other suitable conductive materials. In some embodiments, metal fill 139 can have a resistivity lower than aluminum-free work function metal layer 131, protection layer 133, aluminum-containing work function metal layer 135, and glue layer 137.

Referring to FIGS. 1-3, gate spacers 114 can be disposed on sidewalls of gate structures 120 and sidewall spacers 107 can be disposed on sidewalls of fin structures 108. Gate spacers 114 and sidewall spacers 107 can include insulating materials, such as silicon oxide, silicon nitride, silicon oxynitride, silicon carbonitride, silicon oxycarbide, silicon oxycarbonitride, a low-k material, and a combination thereof. In some embodiments, gate spacers 114 and sidewall spacers 107 can include the same insulating material. In some embodiments, gate spacers 114 and sidewall spacers 107 can include different insulating materials. In some embodiments, gate spacers 114 and sidewall spacers 107 can include a single layer or a stack of insulating layers. In some embodiments, gate spacers 114 and sidewall spacers 107 can include a low-k material with a dielectric constant less than about 3.9 (e.g., about 3.5, about 3.0, or about 2.8).

In some embodiments, as shown in FIGS. 1 and 2, S/D structures 110 can be disposed on the second portion of fin structures 108 and on opposing sides of gate structures 120. S/D structures 110 can be in contact with the first portion of fin structures 108. In some embodiments, as shown in FIGS. 1 and 3, S/D structures 110 can be disposed on fin structures 108 and on opposing sides of gate structures 120. S/D structures 110 can be in contact with nanostructures 122 and inner spacers 121. In some embodiments, S/D structures 110 can function as S/D regions of transistors 102A-102C. In some embodiments, S/D structures 110 can have any geometric shape, such as a polygon, an ellipse, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium, and imparts a strain on the channel regions under gate structures 120. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions. In some embodiments, S/D structures 110 can have a width along an X-axis ranging from about 20nm to about 40nm. In some embodiments, S/D structures 110 can have a height along a Z-axis ranging from about 50nm to about 100nm.

In some embodiments, as shown in FIG. 3, inner spacers 121 can be disposed between gate structures 120 and S/D structures 110. In some embodiments, inner spacers 121 can include dielectric materials, such as silicon oxide, silicon nitride, silicon oxynitride, silicon carbonitride, silicon oxycarbide, silicon oxycarbonitride, a low-k material, and a combination thereof. In some embodiments, inner spacers 121 can be conformal on S/D structures 110 and can have a thickness 121t ranging from about 3nm to about 7nm.

Referring to FIGS. 1-3, ESL 116 can be disposed on STI regions 106, S/D structures 110, and sidewalls of gate spacers 114 and sidewall spacers 107. ESL 116 can be configured to protect STI regions 106, S/D structures 110, and gate structures 120 during the formation of S/D contact structures on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

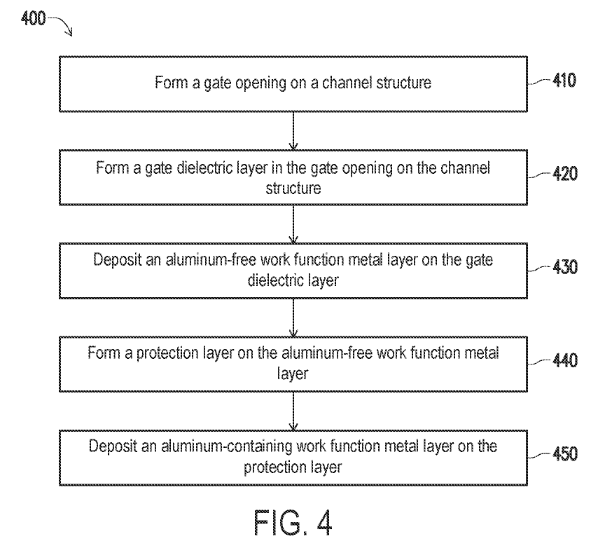

FIG. 4 is a flow diagram of a method 400 for fabricating semiconductor device 100 having gate structures with a protection layer, in accordance with some embodiments. Method 400 may not be limited to nanostructure transistor devices and can be applicable to other devices that would benefit from the gate structures with the protection layer. Additional fabrication operations may be performed between various operations of method 400 and may be omitted merely for clarity and ease of description. Additional processes can be provided before, during, and/or after method 400; one or more of these additional processes are briefly described herein. Moreover, not all operations may be needed to perform the disclosure provided herein. Additionally, some of the operations may be performed simultaneously or in a different order than shown in FIG. 4. In some embodiments, one or more other operations may be performed in addition to or in place of the presently-described operations.

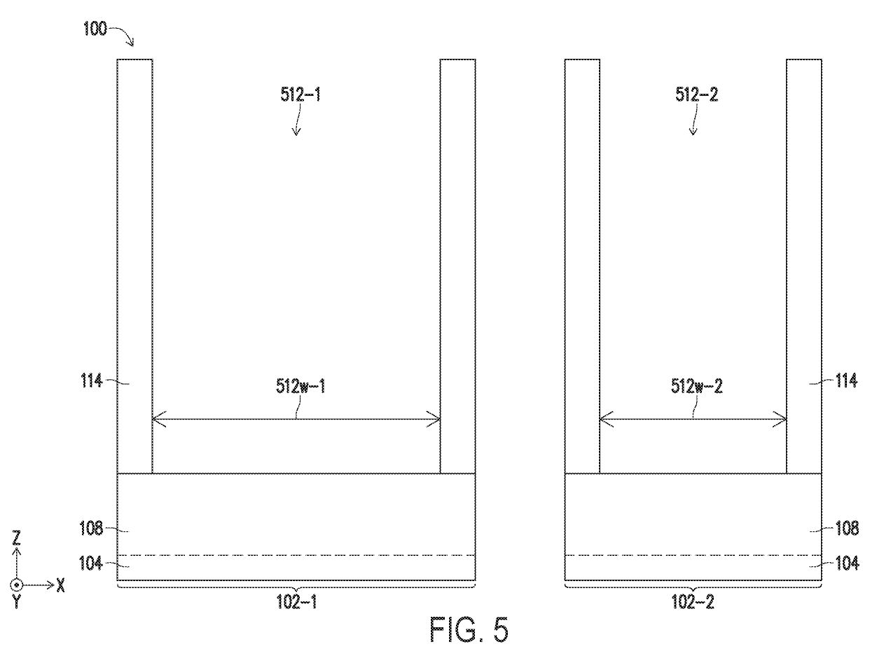

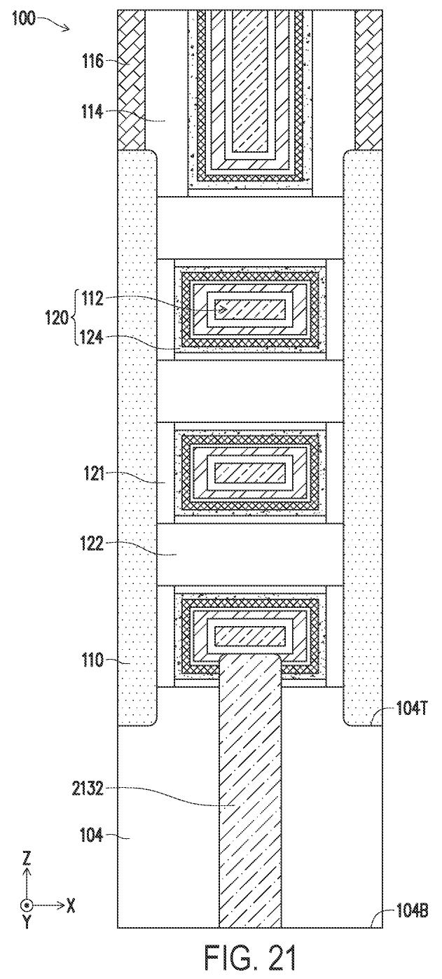

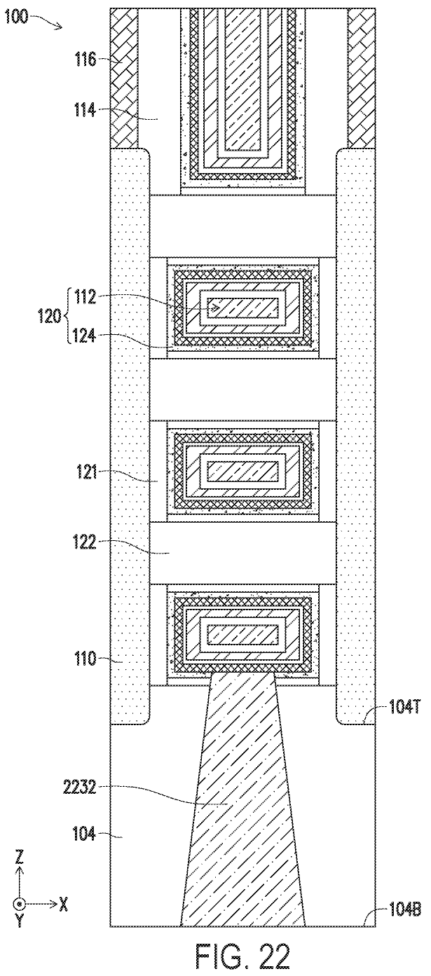

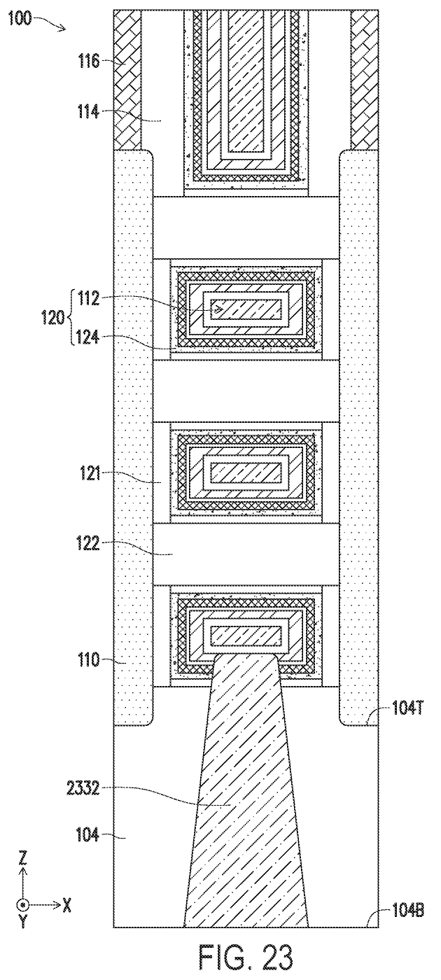

For illustrative purposes, the operations illustrated in FIG. 4 will be described with reference to the example fabrication process for fabricating semiconductor device 100 as illustrated in FIGS. 5-23. FIGS. 5-23 illustrate partial cross-sectional views of semiconductor device 100 having gate structures with a protection layer at various stages of its fabrication, in accordance with some embodiments. In some embodiments, elements in FIGS. 5-23 with the same annotations as elements in FIGS. 1-3 are described above.

In referring to FIG. 4, method 400 begins with operation 410 and the process of forming a gate opening on a channel structure. For example, as shown in FIG. 5, gate openings 512-1 and 512-2 can be formed on fin structures 108, in accordance with some embodiments. In some embodiments, as shown in FIG. 5, gate opening 512-1 can be formed for a large gate transistor 102-1 and gate opening 512-2 can be formed for a small gate transistor 102-2. In some embodiments, large gate transistor 102-1 can have a gate width along an X-axis direction ranging from about 20nm to about 200nm. In some embodiments, large gate transistor 102-1 can include input/output (IO) devices. In some embodiments, small gate transistor 102-2 can have a gate width along an X-axis direction ranging from about 3nm to about 20nm. In some embodiments, small gate transistor 102-2 can include static random access memory (SRAM) devices. In some embodiments, sacrificial gate structures (not shown) of large gate transistor 102-1 and small gate transistor 102-2 can be concurrently removed in an etching process to form openings 512-1 and 512-2, respectively. In some embodiments, each of gate openings 512-1 and 512-2 can be formed between a pair of gate spacers 114. In some embodiments, as shown in FIG. 5, gate openings 512-1 can have a width 512w-1 along an X-axis direction ranging from about 20nm to about 200nm. In some embodiments, gate openings 512-2 can have a width 512w-2 along an X-axis direction ranging from about 3nm to about 20nm.

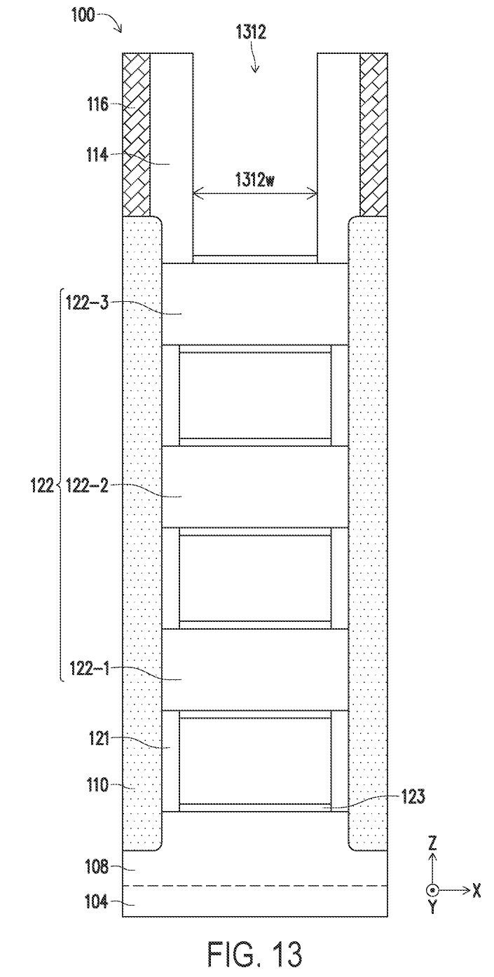

In some embodiments, as shown in FIG. 13, nanostructures 122 and fin structures 108 can be formed on substrate 104 and gate opening 1312 can be formed around nanostructures 122 and on fin structures 108. In some embodiments, nanostructures 122 can be in the form of semiconductor layers, nanosheets, nanowires, or nano-ribbons. In some embodiments, nanostructures 122 and fin structures 108 can include the same semiconductor material as substrate 104. In some embodiments, fin structures 108 can include the same semiconductor material as substrate 104 and nanostructures 122 can include a semiconductor material different from substrate 104. In some embodiments, each of nanostructures 122 can have a thickness along a Z-axis ranging from about 3nm to about 15nm. In some embodiments, gate opening 1312 can be formed by one or more etching processes to remove sacrificial gate structures (not shown) on top nanostructure 122-3 and sacrificial nanostructures (not shown) between nanostructures 122. In some embodiments, inner spacers 121 and ESL 116 can protect S/D structures 110 during the one or more etching processes. In some embodiments, gate openings 1312 can have a width 1312w along an X-axis direction ranging from about 1nm to about 20nm.

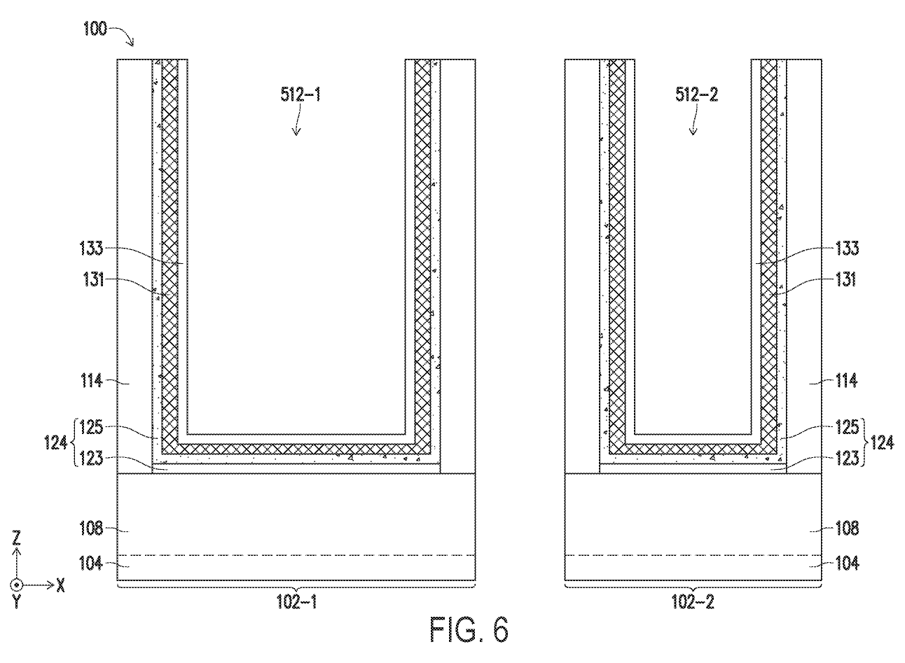

Referring to FIG. 4, in operation 420, a gate dielectric layer is formed in the gate opening on the channel structure. For example, as shown in FIG. 6, gate dielectric layer 124 can be formed in gate openings 512-1 and 512-2 on fin structures 108, in accordance with some embodiments. In some embodiments, the formation of gate dielectric layer 124 can include the formation of interfacial layer 123 on fin structures 108 and the formation of high-k dielectric layer 125 on interfacial layer 123. In some embodiments, interfacial layer 123 can include silicon oxide formed by an oxidation process or a deposition process. In some embodiments, interfacial layer 123 can have a thickness ranging from about 0.1nm to about 1.5nm. In some embodiments, high-k dielectric layer 125 can include hafnium oxide, zirconium oxide, or other suitable high-k dielectric materials deposited by atomic layer deposition (ALD), chemical vapor deposition (CVD), or other suitable deposition methods. In some embodiments, high-k dielectric layer 125 can have a thickness ranging from about 0.2nm to about 10nm.

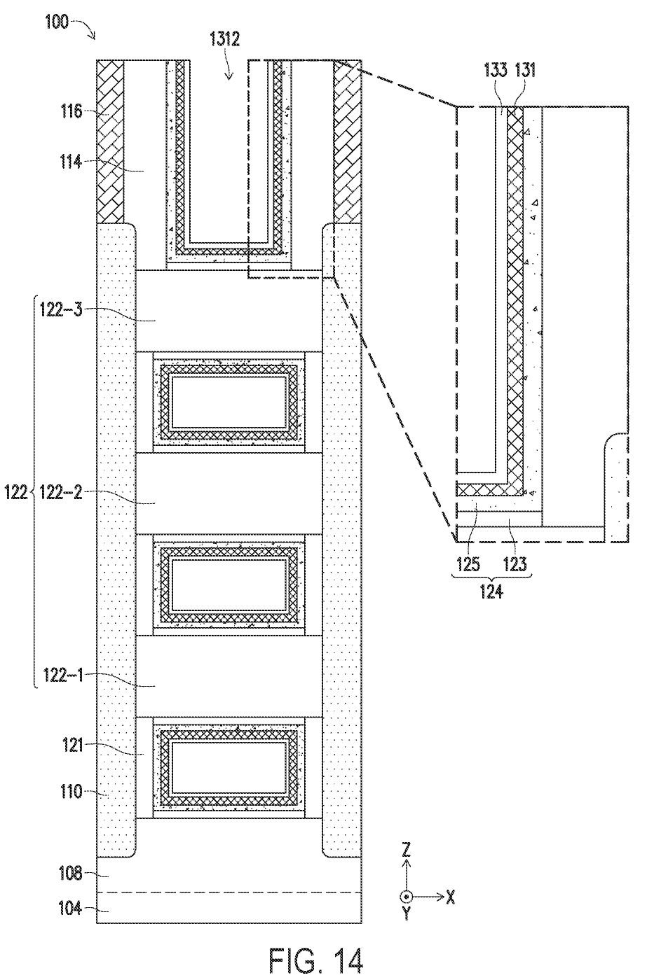

In some embodiments, as shown in FIGS. 13 and 14, gate dielectric layer 124 can be formed in gate opening 1312 surrounding nanostructures 122 and on fin structures 108. In some embodiments, the formation of gate dielectric layer 124 in FIG. 14 can be similar to the formation of gate dielectric layer 124 in FIG. 6 and can include the formation of interfacial layer 123 on nanostructures 122 and fin structures 108 and the formation of high-k dielectric layer 125 on interfacial layer 123. In some embodiments, interfacial layer 123 can include silicon oxide formed by an oxidation process or a deposition process. In some embodiments, high-k dielectric layer 125 can include hafnium oxide, zirconium oxide, or other suitable high-k dielectric materials deposited by ALD, CVD, or other suitable deposition methods.

Referring to FIG. 3, in operation 430, an aluminum-free work function metal layer is deposited on the gate dielectric layer. For example, as shown in FIG. 6, in some embodiments, aluminum-free work function metal layer 131 can be conformally deposited on gate dielectric layer 124 by ALD, CVD, or other suitable deposition methods. In some embodiments, as shown in FIG. 14, aluminum-free work function metal layer 131 can be conformally deposited on gate dielectric layer 124 surrounding nanostructures 122 and on fin structures 108 by ALD, CVD, or other suitable deposition methods. In some embodiments, aluminum-free work function metal layer 131 in FIG. 14 can be deposited in the same way as aluminum-free work function metal layer 131 in FIG. 6. In some embodiments, aluminum-free work function metal layer 131 can include titanium nitride, titanium silicon nitride, tantalum nitride, tungsten carbon nitride, tungsten, ruthenium, molybdenum, or other suitable work function materials. In some embodiments, aluminum-free work function metal layer 131 can include materials having a work function greater than about 4.4 eV.

In some embodiments, aluminum-free work function metal layer 131 can include a single metal layer or a stack of metal layers. The stack of metal layers can include work function metals having work-function values equal to or different from each other. In some embodiments, aluminum-free work function metal layer 131 can have a thickness ranging from about 0.1nm to about 8nm. In some embodiments, aluminum-free work function metal layer 131 can tune, primarily, the threshold voltage of p-type FETs (and to a much lesser degree the threshold voltage of the n-type FETs). In some embodiments, n-type FETs may not be affected by the presence of aluminum-free work function metal layer 131.

Referring to FIG. 3, in operation 440, a protection layer is formed on the aluminum-free work function metal layer. For example, as shown FIGS. 6 and 14, protection layer 133 can be formed on aluminum-free work function metal layer 131. In some embodiments, protection layer 133 can be conformally deposited on aluminum-free work function metal layer 131 by ALD, CVD, or other suitable deposition methods. In some embodiments, protection layer 133 can include a conductive material having elements of oxygen and/or carbon. In some embodiments, protection layer 133 can include titanium carbonitride, titanium oxynitride, tungsten carbonitride, titanium silicon oxide, or other suitable conductive materials.

In some embodiments, protection layer 133 can block the diffusion of aluminum from subsequently formed aluminum-containing work function metal layer 135 towards aluminum-free work function metal layer 131 and gate dielectric layer 124. Aluminum diffused to gate dielectric layer 124 can cause device reliability issues. With protection layer 133, aluminum diffusion from aluminum-containing work function metal layer 135 can be blocked and device reliability of semiconductor device 100 can be improved. In some embodiments, protection layer 133 can have a thickness ranging from about 0.05nm and about 1nm to improve the block of aluminum diffusion and reduce the resistance of gate electrode 112.

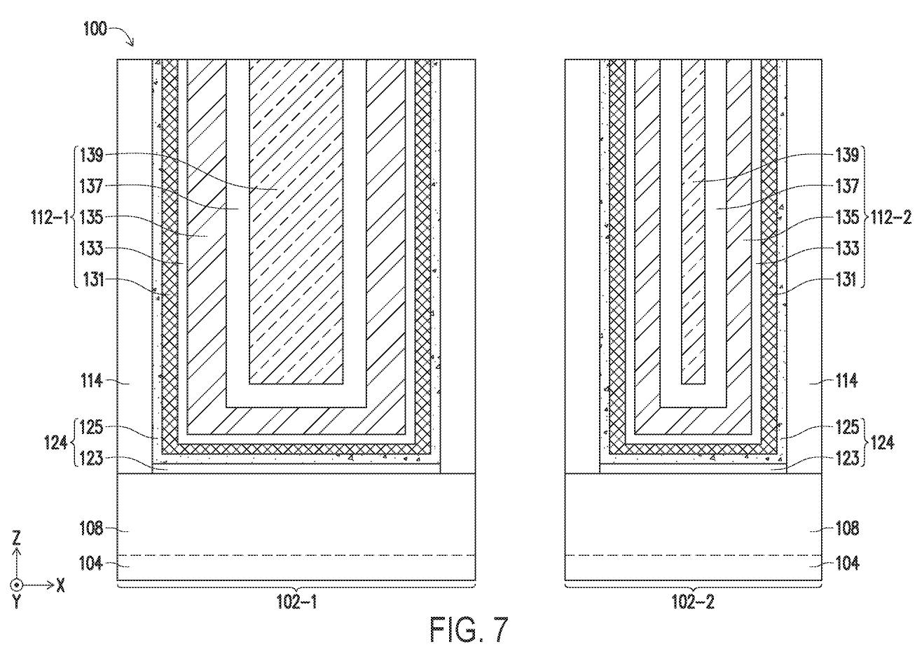

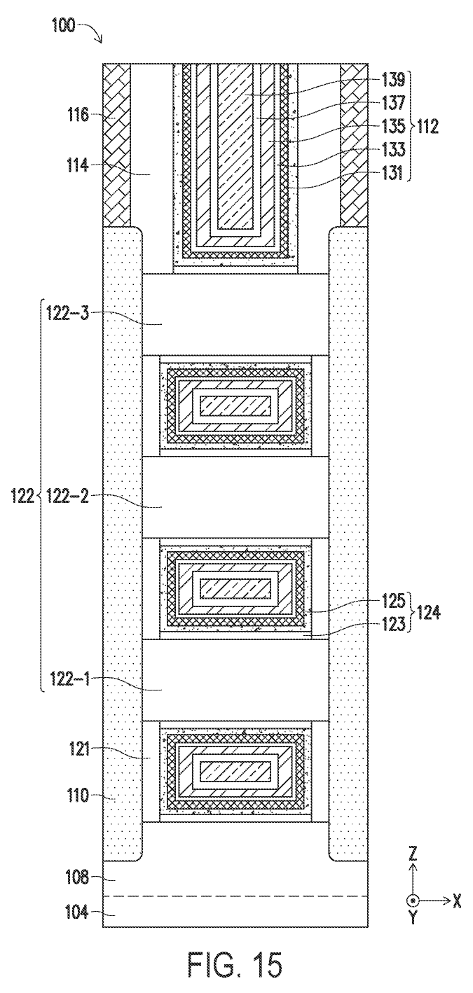

Referring to FIG. 3, in operation 450, an aluminum-containing work function metal layer is deposited on the protection layer. For example, as shown FIG. 7, in some embodiments, aluminum-containing work function metal layer 135 can be conformally deposited on protection layer 133 by ALD, CVD, or other suitable deposition methods. In some embodiments, as shown in FIG. 15, aluminum-containing work function metal layer 135 can be conformally deposited on protection layer 133 surrounding nanostructures 122 and on fin structures 108. In some embodiments, aluminum-containing work function metal layer 135 in FIG. 15 can be deposited in the same way as aluminum-containing work function metal layer 135 in FIG. 7. In some embodiments, aluminum-containing work function metal layer 135 can include aluminum, titanium aluminum, titanium aluminum carbon, tantalum aluminum, tantalum aluminum carbon, or other suitable work function material. In some embodiments, aluminum-containing work function metal layer 135 can include materials having a work function less than about 4.4 eV.

In some embodiments, aluminum-containing work function metal layer 135 can include a single metal layer or a stack of metal layers. The stack of metal layers can include work function metals having work function values equal to or different from each other. In some embodiments, aluminum-containing work function metal layer 135 can have a thickness ranging from about 0.2nm and about 8nm. In some embodiments, aluminum-containing work function metal layer 135 can tune, primarily, the threshold voltage of n-type FETs. In some embodiments, aluminum-containing work function metal layer 135 can be present in each transistor of semiconductor device 100.

After the deposition of aluminum-containing work function metal layer 135, glue layer 137 and metal fill 139 can be deposited on aluminum-containing work function metal layer 135 to form gate electrode 112, as shown in FIGS. 7 and 15. In some embodiments, glue layer 137 can be conformally deposited on aluminum-containing work function metal layer 135 by ALD, CVD, or other suitable deposition methods. In some embodiments, glue layer 137 can provide sufficient bonding between metal fill 139 and aluminum-containing work function metal layer 135. In some embodiments, glue layer 137 can include cobalt, titanium, titanium nitride, titanium silicon oxide, or other suitable conductive materials. In some embodiments, glue layer 137 can have a thickness ranging from about 0.2nm to about 10nm. In some embodiments, glue layer 137 is optional and gate electrode 112 can include no glue layer and more metal fill 139 to have a lower resistance.

In some embodiments, metal fill 139 can be deposited by CVD, ALD, or other suitable deposition methods. In some embodiments, metal fill 139 can include titanium, tantalum, aluminum, cobalt, tungsten, nickel, ruthenium, or other suitable conductive materials. In some embodiments, metal fill 139 can have a resistivity lower than aluminum-free work function metal layer 131, protection layer 133, aluminum-containing work function metal layer 135, and glue layer 137. In some embodiments, the deposition of metal fill 139 can be followed by a chemical mechanical polishing (CMP) process to planarize top surfaces of gate spacers 114, gate dielectric layer 124, aluminum-free work function metal layer 131, protection layer 133, aluminum-containing work function metal layer 135, glue layer 137, and metal fill 139. Gate electrodes 112 can be formed on gate dielectric layer 124 and gate structures 120 can be formed on fin structures 108 and nanostructures 122. In some embodiments, as described above, the gate width of large gate transistor 102-1 can be greater than the gate width of small gate transistor 102-2. Accordingly, a first length of the channel structure (e.g., fin structures 108 under gate structures 120) of large gate transistors 102-1 can be greater than a second length of the channel structure (e.g., fin structures 108 under gate structures 120) in small gate transistors 102-2.

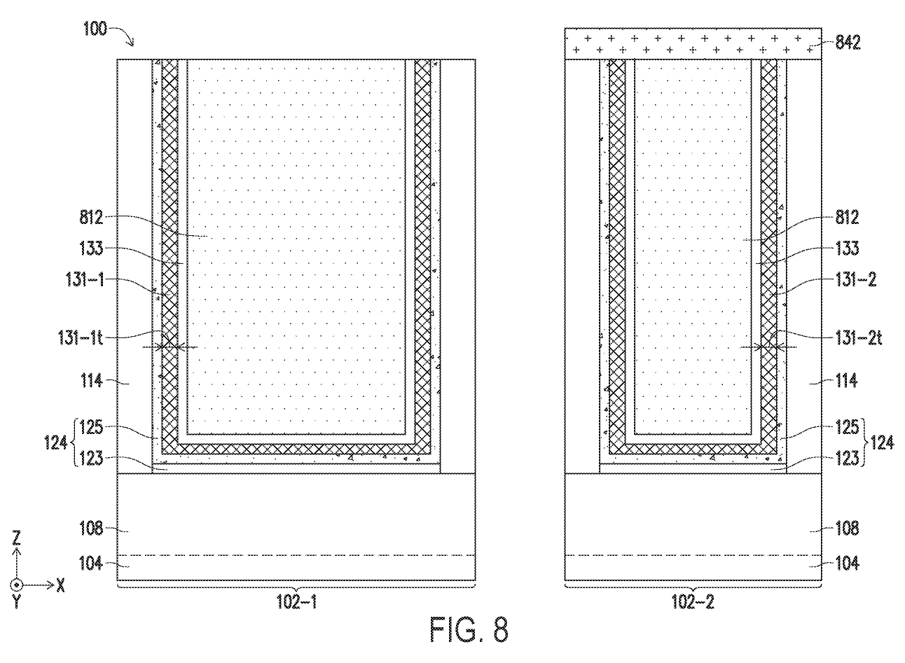

In some embodiments, protection layer 133 can be optional for large gate transistor 102-1 and thus can be removed for large gate transistor 102-1, as shown in FIGS. 8-10. In some embodiments, as shown in FIG. 8, gate dielectric layer 124 and aluminum-free work function metal layers 131-1 and 131-2 can be formed on fin structures 108 as described in operations 410, 420, and 430. In some embodiments, aluminum-free work function metal layers 131-1 of large gate transistor 102-1 can have a thickness 131-1t ranging from about 0.2nm to about 10nm. In some embodiments, aluminum-free work function metal layers 131-2 of small gate transistor 102-2 can have a thickness 131-2t ranging from about 0.1nm to about 8nm. In some embodiments, thickness 131-1t of aluminum-free work function metal layers 131-1 in large gate transistor 102-1 can be greater than thickness 131-2t of aluminum-free work function metal layers 131-2 in small gate transistor 102-2.

In some embodiments, transistors with aluminum-free work function metal layers 131-1 and 131-2 having different thicknesses can be formed by a sequence of photolithography and etching operations. In some embodiments, aluminum-free work function metal layers 131-1 can be deposited concurrently on both large gate transistor 102-1 and small gate transistor 102-2. In some embodiments, large gate transistor 102-1 can be subsequently masked with a photoresist so that aluminum-free work function metal layers 131-1 in small gate transistor 102-2 can be etched to form thinner aluminum-free work function metal layers 131-2. Once aluminum-free work function metal layers 131-2 is formed, the photoresist can be removed from large gate transistor 102-1. In some embodiments, the formation sequence described above is not limiting and other sequences to form aluminum-free work function metal layers having different thicknesses using similar or different operations may be performed.

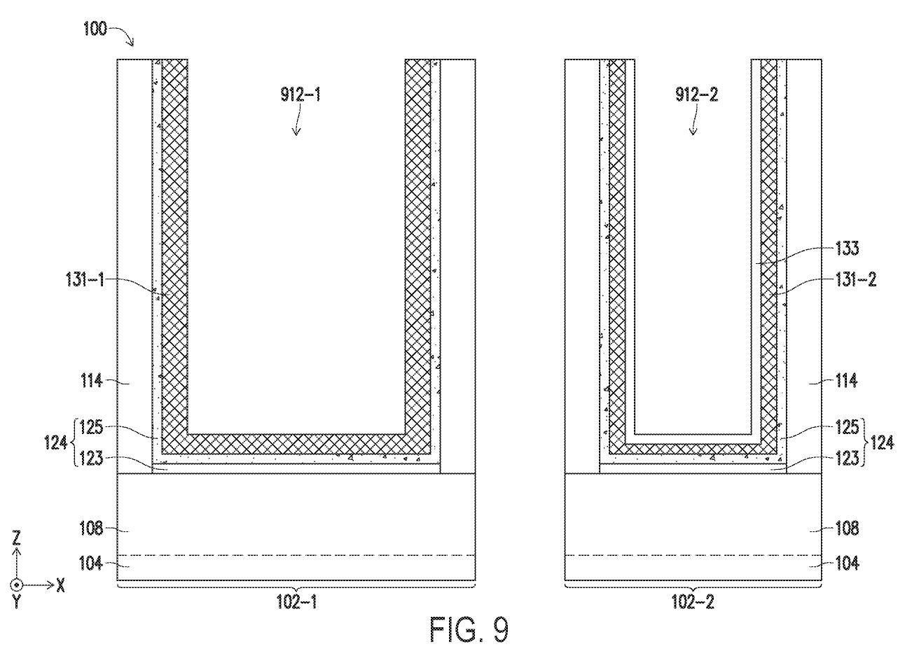

In some embodiments, as shown in FIG. 8, after the formation of aluminum-free work function metal layers 131-1 and 131-2, protection layer 133 can be concurrently formed on aluminum-free work function metal layers 131-1 in large gate transistor 102-1 and on aluminum-free work function metal layers 131-2 in small gate transistor 102-2. In some embodiments, protection layer 133 on aluminum-free work function metal layers 131-1 in large gate transistor 102-1 can be removed by a sequence of photolithography and etching operations. In some embodiments, a photo layer 812 can be formed on protection layer 133. A mask layer 842 can be formed on photo layer 812 and patterned to cover small gate transistor 102-2. Subsequently, one or more etching processes can remove photo layer 812 and protection layer 133 on large gate transistor 102-1. After photo layer 812 and mask layer 842 are removed, gate opening 912-1 can be formed on large gate transistor 102-1 and gate opening 912-2 can be formed on small gate transistor 102-2, as shown in FIG. 9.

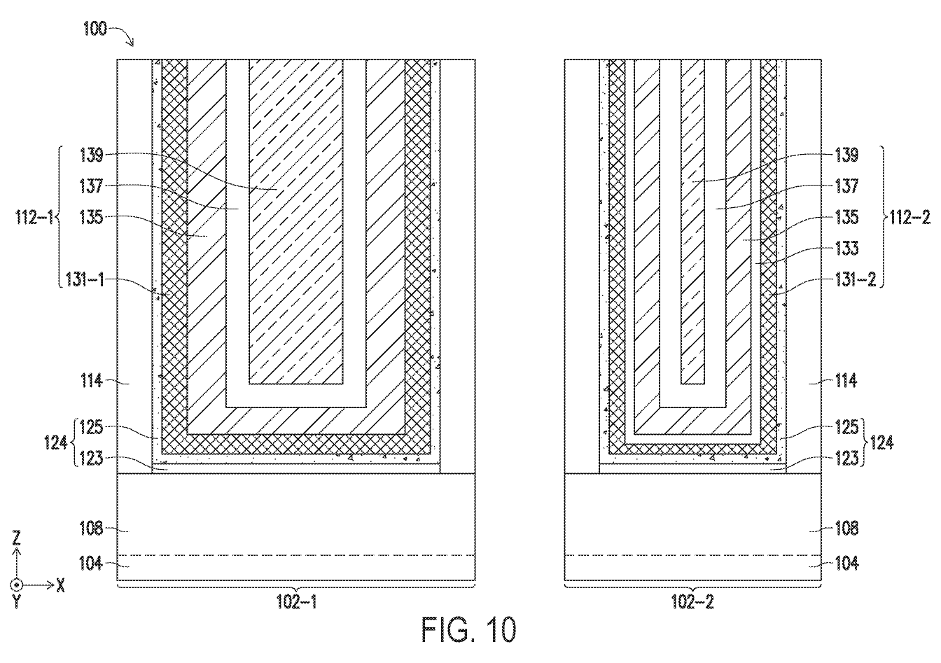

In some embodiments, as shown in FIG. 10, aluminum-containing work function metal layer 135 can be formed on aluminum-free work function metal layer 131-1 in large gate transistor 102-1 and on protection layer 133 in small gate transistor 102-2, as described in operation 450. In some embodiments, glue layer 137 and metal fill 139 can be formed on aluminum-containing work function metal layer 135 and fill gate openings 912-1 and 912-2, as shown in FIG. 10. In some embodiments, a CMP process can be performed to planarize top surfaces of gate spacers 114, gate dielectric layer 124, aluminum-free work function metal layers 131-1 and 131-2, protection layer 133, aluminum-containing work function metal layer 135, glue layer 137, and metal fill 139, as shown in FIG. 10. Accordingly, gate electrode 112-1 with aluminum-free work function metal layers 131-1 can be formed on large gate transistor 102-1 and gate electrode 112-2 with aluminum-free work function metal layers 131-2 and protection layer 133 can be formed on small gate transistor 102-2. In some embodiments, protection layer 133 in small gate transistor 102-2 can block the diffusion of aluminum from aluminum-containing work function metal layer 135 towards aluminum-free work function metal layer 131-2 and gate dielectric layer 124. In some embodiments, thicker aluminum-free work function metal layer 131-1 in large gate transistor 102-1 can block the diffusion of aluminum from aluminum-containing work function metal layer 135 towards gate dielectric layer 124 without significantly increasing the resistance of gate electrode 112. As a result, device reliability of small gate transistor 102-2 and large gate transistor 102-1 in semiconductor device 100 can be improved.

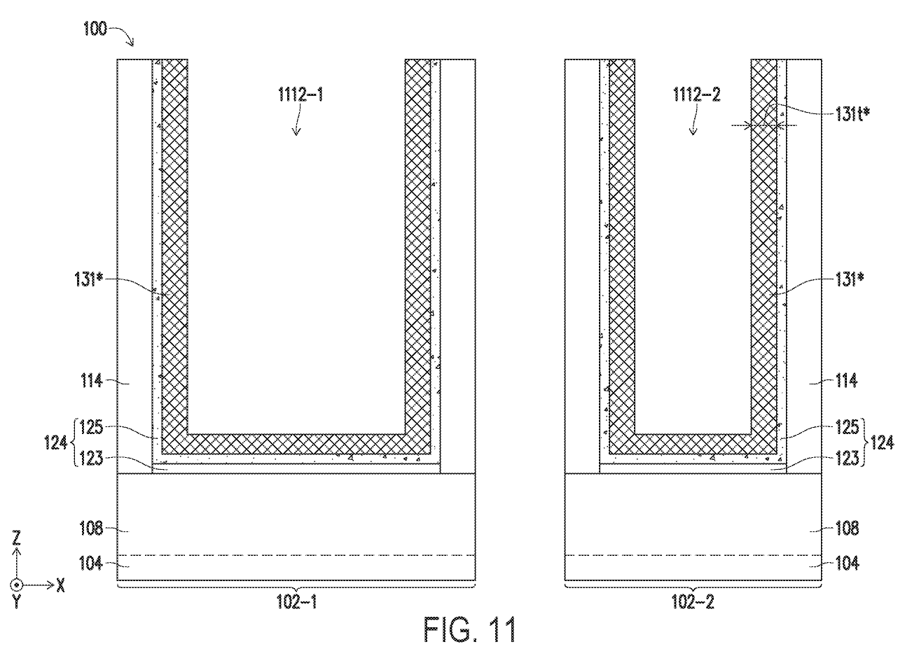

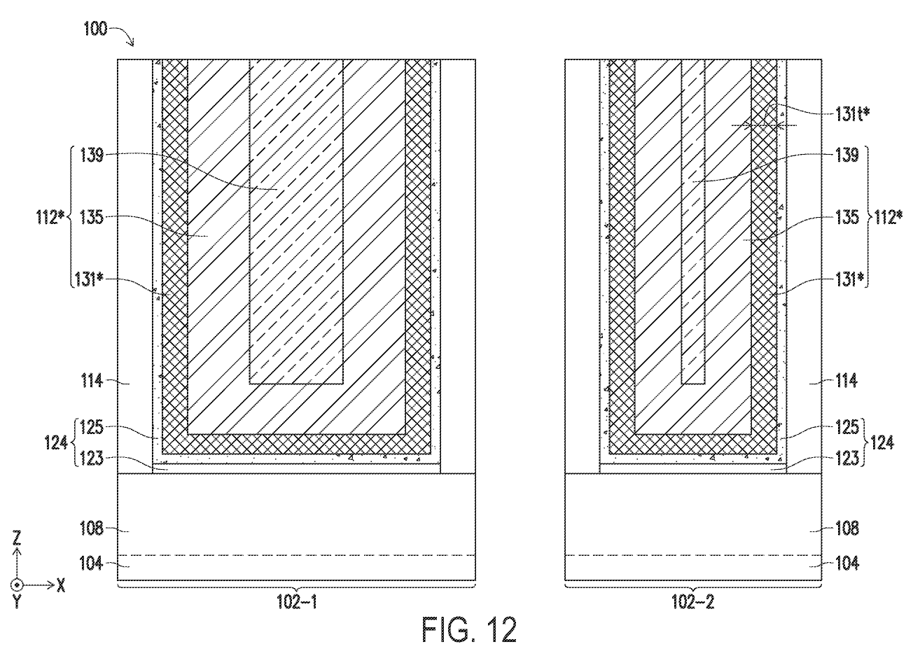

In some embodiments, glue layer 137 is optional and can be removed for large gate transistor 102-1 and small gate transistor 102-2, as shown in FIGS. 11 and 12. With the removal of glue layer 137, gate electrode 112 can have thicker aluminum-free work function metal layers 131* to block the aluminum diffusion from aluminum-containing work function metal layer 135. In some embodiments, thicker aluminum-free work function metal layers 131* may not significantly increase the resistance of gate electrode 112*. In some embodiments, as shown in FIG. 11, gate dielectric layer 124 and aluminum-free work function metal layer 131* can be formed in gate openings 1112-1 and 1112-2 on fin structures 108 as described in operations 410, 420, and 430. In some embodiments, as shown in FIG. 12, aluminum-containing work function metal layer 135 can be conformally deposited on aluminum-free work function metal layers 131* in large gate transistor 102-1 and small gate transistor 102-2. Metal fill 139 can be deposited on aluminum-containing work function metal layer 135 to fill gate openings 1112-1 and 1112-2 and form gate electrode 112*. In some embodiments, a CMP process can be performed to planarize top surfaces of gate spacers 114, gate dielectric layer 124, aluminum-free work function metal layer 131*, aluminum-containing work function metal layer 135, and metal fill 139, as shown in FIG. 12.

In some embodiments, aluminum-free work function metal layer 131* can have a thickness 131t* ranging from about 0.2nm to about 10nm. In some embodiments, a ratio of thickness 131t* for aluminum-free work function metal layer 131* to thickness 125t for high-k dielectric layer 125 can range from about 0.8 to about 1.2. If thickness 131t* is less than about 0.2nm or the ratio is less than about 0.8, aluminum-free work function metal layer 131* may not block the aluminum diffusion from aluminum-containing work function metal layer 135. If thickness 131t* is greater than about 10nm or the ratio is greater than about 1.2, gate electrode 112* may not have enough space for metal fill 139, especially in small gate transistor 102-2, and the resistance of gate electrode 112* may increase. Accordingly, as shown in FIG. 12, large gate transistor 102-1 and small gate transistor 102-2 can have no protection layer 133 and thicker aluminum-free work function metal layers 131* to reduce the resistance of gate electrode 112* and block the aluminum diffusion from aluminum-containing work function metal layer 135.

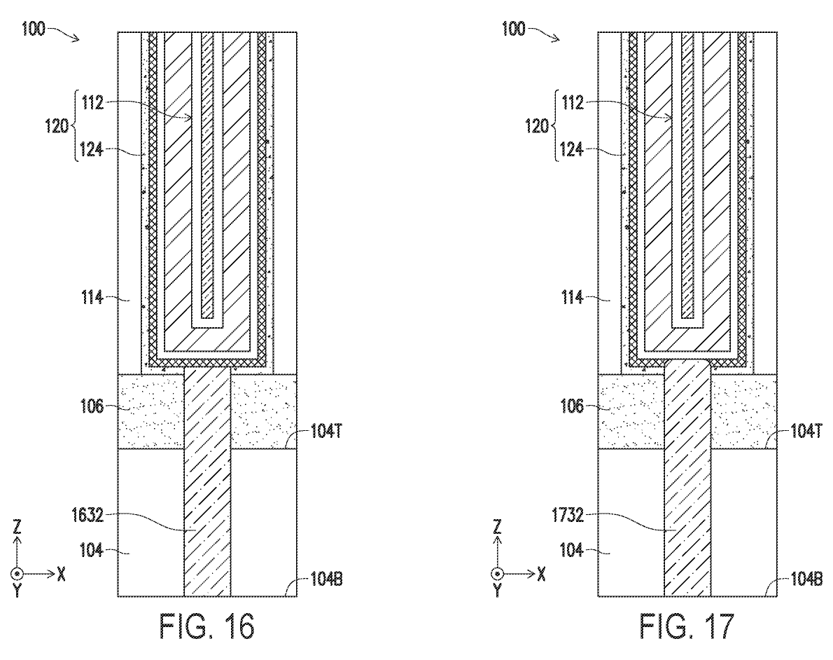

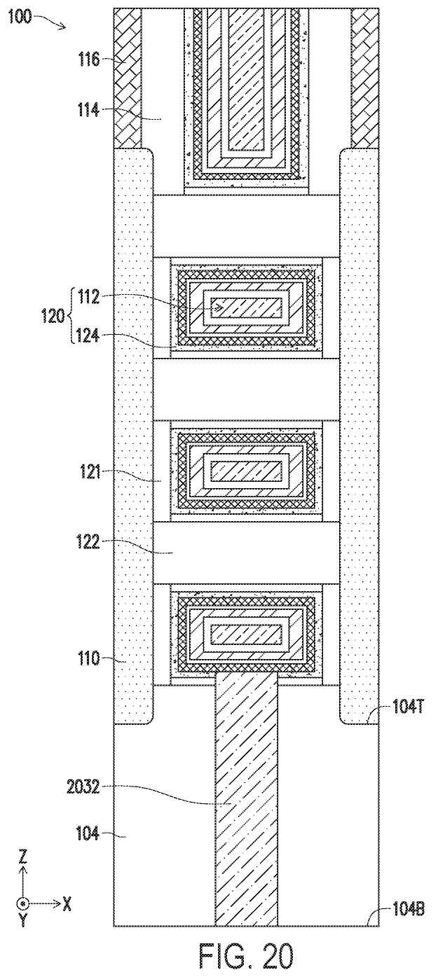

In some embodiments, after the formation of gate structures 120, backside gate contacts can be formed in contact with gate structures 120. In some embodiments, as shown in FIGS. 16-19, transistors 102A-102C with gate structures 120 can be formed on a top surface 104T of substrate 104. Backside gate contacts 1632, 1732, 1832, and 1932 can be formed on a bottom surface 104B extending through substrate 104 and STI regions 106 to contact gate structures 120. In some embodiments, as shown in FIGS. 20-23, transistors 102A-102C with gate structures 120 can be formed on top surface 104T of substrate 104. Backside gate contacts 2032, 2132, 2232, and 2332 can be formed on bottom surface 104B extending through substrate 104 to contact gate structures 120 below nanostructures 122.

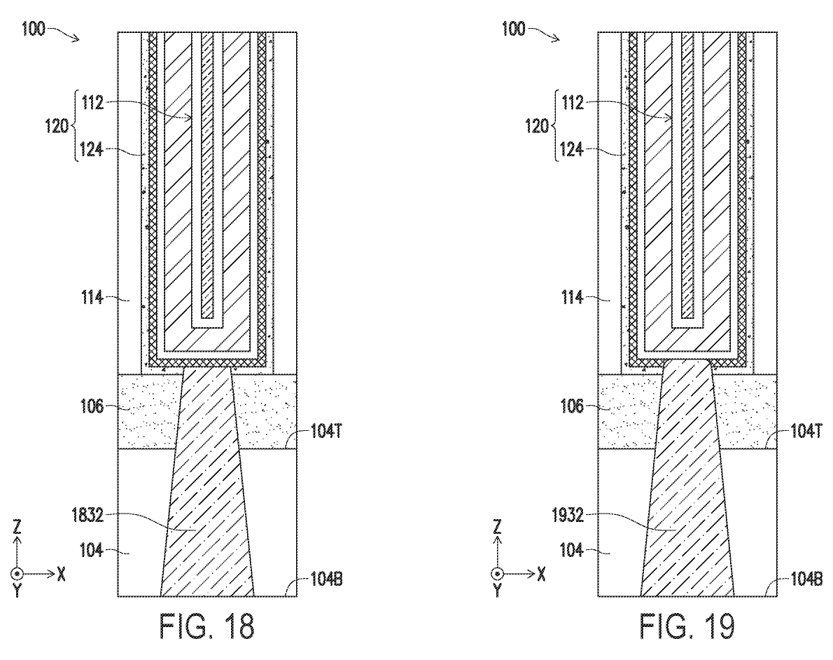

In some embodiments, as shown in FIGS. 16, 17, 20, and 21, backside gate contacts 1632, 1732, 2032, and 2132 can have a straight profile. In some embodiments, straight backside gate contacts 1632, 1732, 2032, and 2132 can improve device performance of semiconductor device 100. In some embodiments, as shown in FIGS. 18, 19, 22, and 23, backside gate contacts 1832, 1932, 2232, and 2332 can have a tapered profile. In some embodiments, tapered backside gate contacts 1832, 1932, 2232, and 2332 can improve the filling of these backside gate contacts and can avoid the formation of voids in these backside gate contacts.

In some embodiments, backside gate contacts 1632, 1832, 2032, and 2232 can just land on gate electrode 112 (e.g., in contact with aluminum-free work function metal layer 131), as shown in FIGS. 16, 18, 20, and 22. In some embodiments, backside gate contacts 1632, 1832, 2032, and 2232 can reduce gate electrode damage and improve threshold voltage and leakage current control of semiconductor device 100. In some embodiments, backside gate contacts 1732, 1932, 2132, and 2332 can extend through aluminum-free work function metal layer 131 and/or protection layer 133 into gate electrode 112, as shown in FIGS. 17, 19, 21, and 23. In some embodiments, backside gate contacts 1732, 1932, 2132, and 2332 can extend into gate electrode 112 by a depth ranging from about 0.5nm to about 2nm. In some embodiments, backside gate contacts 1732, 1932, 2132, and 2332 can reduce the contact resistance between these backside gate contacts and gate electrode 112.

Various embodiments in the present disclosure provide methods for forming gate structures with a protection layer in semiconductor device 100. In some embodiments, semiconductor device 100 can include a channel structure (e.g., fin structures 108 or nanostructures 122) on substrate 104. Gate dielectric layer 124 can be disposed on the channel structure. Aluminum-free work function metal layer 131 can be disposed on gate dielectric layer 124 and can surround the channel structure. Protection layer 133 can be disposed on aluminum-free work function metal layer 131. Aluminum-containing work function metal layer 135 can be disposed on protection layer 133. Metal fill 139 can be disposed on aluminum-containing work function metal layer 135. In some embodiments, protection layer 133 can block the aluminum diffusion from aluminum-containing work function metal layer 135 towards gate dielectric layer 124 and the channel structure and improve the reliability of semiconductor device 100. In some embodiments, with protection layer 133, a thickness of aluminum-free work function metal layer 131 can be scaled down and the space for metal fill 139 can increase, which can reduce the gate resistance of semiconductor device 100 and improve the device performance.

In some embodiments, a semiconductor device includes a channel structure on a substrate, an isolation structure surrounding the channel structure, a gate dielectric layer on the channel structure and the isolation structure, an aluminum-free work function metal layer on the gate dielectric layer, a protection layer on the aluminum-free work function metal layer, and an aluminum-containing work function metal layer on the protection layer.

In some embodiments, a semiconductor device includes a channel structure on a substrate, a source/drain structure on the substrate and in contact with the channel structure, a pair of spacers on the channel structure, a gate dielectric layer on the channel structure and the pair of spacers, and a gate electrode on the gate dielectric layer and between the pair of spacers. The gate dielectric layer is between the source/drain structure and a spacer of the pair of spacers. The gate electrode includes an aluminum-free work function metal layer on the gate dielectric layer, a protection layer on the aluminum-free work function metal layer, and an aluminum-containing work function metal layer on the protection layer.

In some embodiments, a method includes forming a gate opening on a channel structure, forming a gate dielectric in the gate opening on the channel structure, depositing an aluminum-free work function metal layer on the gate dielectric layer, forming a protection layer on the aluminum-free work function metal layer, and depositing an aluminum-containing work function metal layer on the protection layer. The gate opening is between a pair of spacers on the channel structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a channel structure on a substrate;
an isolation structure surrounding the channel structure;
a gate dielectric layer on the channel structure and the isolation structure;
an aluminum-free work function metal layer on the gate dielectric layer;
a protection layer on the aluminum-free work function metal layer; and
an aluminum-containing work function metal layer on the protection layer.

2. The semiconductor device of claim 1, further comprising a glue layer on the aluminum-containing work function metal layer and a metal fill on the glue layer.

3. The semiconductor device of claim 1, wherein the protection layer comprises an element of oxygen or carbon.

4. The semiconductor device of claim 1, wherein the protection layer comprises titanium carbonitride, titanium oxynitride, tungsten carbonitride, or titanium silicon oxide.

5. The semiconductor device of claim 1, further comprising an additional channel structure, wherein:
the additional channel structure is longer than the channel structure;
the gate dielectric layer is on the additional channel structure;
the aluminum-free work function metal layer is on the gate dielectric layer;
the protection layer is on the aluminum-free work function metal layer; and
the aluminum-containing work function metal layer is on the protection layer.

6. The semiconductor device of claim 1, further comprising an additional channel structure, wherein:
the additional channel structure is longer than the channel structure;
the gate dielectric layer is on the additional channel structure;
an additional aluminum-free work function metal layer is on the gate dielectric layer, wherein the additional aluminum-free work function metal layer is thicker than the aluminum-free work function metal layer; and
the aluminum-containing work function metal layer is on the aluminum-free work function metal layer.

7. The semiconductor device of claim 1, further comprising a gate contact structure in contact with the aluminum-free work function metal layer.

8. The semiconductor device of claim 1, further comprising a gate contact structure extending through the aluminum-free work function metal layer and into the protection layer.

9. The semiconductor device of claim 1, wherein top surfaces of the aluminum-free work function metal layer, the protection layer, and the aluminum-containing work function metal layer are coplanar.

10. The semiconductor device of claim 1, wherein the channel structure comprises a plurality of nanostructures, and wherein the protection layer wraps around each of the plurality of nanostructures.

11. A semiconductor device, comprising:
a channel structure on a substrate;
a source/drain structure on the substrate and in contact with the channel structure;
a pair of spacers on the channel structure;
a gate dielectric layer on the channel structure and the pair of spacers, wherein the gate dielectric layer is between the source/drain structure and a spacer of the pair of spacers; and
a gate electrode on the gate dielectric layer and between the pair of spacers, wherein the gate electrode comprises:
an aluminum-free work function metal layer on the gate dielectric layer;
a protection layer on the aluminum-free work function metal layer; and
an aluminum-containing work function metal layer on the protection layer.

12. The semiconductor device of claim 11, wherein the gate electrode further comprise a glue layer on the aluminum-containing work function metal layer and a metal fill on the glue layer.

13. The semiconductor device of claim 12, wherein top surfaces of the aluminum-free work function metal layer, the protection layer, the aluminum-containing work function metal layer, and the metal fill are coplanar.

14. The semiconductor device of claim 11, wherein the protection layer comprises oxygen or carbon.

15. The semiconductor device of claim 11, wherein the protection layer comprises titanium carbonitride, titanium oxynitride, tungsten carbonitride, or titanium silicon oxide.

16. A method, comprising:
forming a gate opening on a channel structure, wherein the gate opening is between a pair of spacers on the channel structure;
forming a gate dielectric layer in the gate opening on the channel structure;
depositing an aluminum-free work function metal layer on the gate dielectric layer;
forming a protection layer on the aluminum-free work function metal layer; and
depositing an aluminum-containing work function metal layer on the protection layer.

17. The method of claim 16, further comprising depositing a glue layer on the aluminum-containing work function metal layer and depositing a metal fill on the glue layer.

18. The method of claim 16, wherein forming the protection layer comprises depositing a conductive material comprising oxygen or carbon.

19. The method of claim 16, wherein forming the protection layer comprises depositing a conductive material comprising titanium carbonitride, titanium oxynitride, tungsten carbonitride, or titanium silicon oxide.

20. The method of claim 16, further comprising planarizing top surfaces of the aluminum-free work function metal layer, the protection layer, and the aluminum-containing work function metal layer.
